(19) United States
(12) Patent Application Publication
(10) Pub. No.: US 2025/0279339 A1
(43) Pub. Date: Sep. 4, 2025

(54) SEMICONDUCTOR DEVICE AND EXTERNAL CONNECTION MAIN TERMINAL

(71) Applicant: FUJI ELECTRIC CO., LTD., Kawasaki-shi (JP)

(72) Inventor: Yoshihiro KODAIRA, Matsumoto-city (JP)

(73) Assignee: FUJI ELECTRIC CO., LTD., Kawasaki-shi (JP)

(21) Appl. No.: 19/041,165

(22) Filed: Jan. 30, 2025

(30) Foreign Application Priority Data
Feb. 29, 2024 (JP) 2024-029288

(51) Int. Cl. H01L 23/495; H01L 23/10; H01L 23/31

(52) U.S. Cl. CPC H01L 23/49555; H01L 23/10; H01L 23/3157

(57) ABSTRACT

An external connection main terminal includes a P main terminal and an N main terminal. The P main terminal includes an external terminal, a horizontal portion of a planar trapezoidal shape parallel to an insulated circuit substrate, and a connection terminal extending obliquely or vertically from the horizontal portion toward the insulated circuit substrate. The N main terminal includes an external terminal, a horizontal portion of a planar trapezoidal shape parallel to the insulated circuit substrate and being located over the horizontal portion of the P main terminal so that the horizontal portions of the P and N main terminals are superimposed over each other with a predetermined gap between in a direction orthogonal to the insulated circuit substrate, and a connection terminal extending obliquely or vertically from the horizontal portion toward the insulated circuit substrate.

### CROSS-REFERENCE TO RELATED APPLICATION

This application is based upon and claims the benefit of priority of the prior Japanese Patent Application No. 2024-029288, filed on Feb. 29, 2024, the entire contents of which are incorporated herein by reference.

### BACKGROUND OF THE INVENTION

### 1. Field of the Invention

The present embodiment discussed herein relates to a semiconductor device and an external connection main terminal.

### 2. Background of the Related Art

In a semiconductor device, a collector electrode joint portion and an emitter electrode joint portion are located at the same position in an up-and-down direction and are adjacent in a right-and-left direction at a predetermined interval (see, for example, Japanese Laid-open Patent Publication No. 2013-021107). A wiring holding portion is provided that holds a first lead frame connected to a first conductive plate and having a first wiring portion wired parallel to a substrate principal surface and a second lead frame connected to a second conductive plate and having a second wiring portion wired above the front surface of the first wiring portion with a gap therebetween so as to overlap the first wiring portion (see, for example, International Publication Pamphlet No. WO 2021/029150). There is a region where a positive-electrode-side lead frame and a negative-electrode-side lead frame overlap each other (see, for example, Japanese Laid-open Patent Publication No. 2023-000131, Japanese Laid-open Patent Publication No. 2023-014524, Japanese Laid-open Patent Publication No. 2023-144474, and International Publication Pamphlet No. WO 2018/142863).

### SUMMARY OF THE INVENTION

According to one aspect, there is provided a semiconductor device including: an insulated circuit substrate group including a plurality of insulated circuit substrates that are arranged on one plane; and an external connection main terminal formed of a first main terminal and a second main terminal in an integral manner, the first main terminal including a positive external terminal connected to a positive electrode of an external power supply, a first lead frame portion having a first planar trapezoidal shape parallel to the one plane, and being connected to the positive external terminal, and a first substrate connection portion extending obliquely or vertically from an edge of the first lead frame portion toward the insulated circuit substrate group, the second main terminal placed over the first main terminal and including a negative external terminal connected to a negative electrode of the external power supply, a second lead frame portion having a second planar trapezoidal shape parallel to the one plane, and being connected to the negative external terminal, the second lead frame portion located over the first lead frame portion having a predetermined gap therebetween in a direction orthogonal to the one plane, and a second substrate connection portion extending obliquely or vertically from an edge of the second lead frame portion toward the insulated circuit substrate group.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a first plan view of a semiconductor device;

FIG. 2 is a side view of the semiconductor device;

FIG. 3 is a sectional view of the semiconductor device;

FIG. 4 illustrates a second plan view of the semiconductor device;

FIG. 5 is a third plan view of the semiconductor device;

FIG. 6 is a fourth plan view of the semiconductor device;

FIG. 7 illustrates an equivalent circuit modeling the function of the semiconductor device;

FIG. 8 illustrates the configuration of a PN main terminal according to a first reference example;

FIG. 9 illustrates the configuration of a PN main terminal according to a second reference example;

FIG. 10 illustrates the configuration of a PN main terminal according to a third reference example;

FIG. 11 illustrates the evaluation of the PN main terminals in the first, second, and third reference examples;

FIG. 12 illustrates an example of the configuration of a PN main terminal according to the present embodiment;

FIGS. 13A and 13B illustrate a first example of the extending directions of connection terminals of the PN main terminal, with FIG. 13A illustrating the extending directions of the connection terminals of the P main terminal and FIG. 13B illustrating the extending directions of the connection terminals of the N main terminal;

FIGS. 14A and 14B illustrate a second example of the extending directions of the connection terminals of the PN main terminal, with FIG. 14A illustrating the extending directions of the connection terminals of the P main terminal and FIG. 14B illustrating the extending directions of the connection terminals of the N main terminal;

FIG. 15 is a view for describing the inclination angles and connection positions of the connection terminals provided in the P main terminal;

FIG. 16 is a view for describing the inclination angles and connection positions of the connection terminals provided in the N main terminal;

FIG. 17 illustrates an example of the configuration of the PN main terminal according to the present embodiment;

FIG. 18 is a view for describing a projection of an insulator;

FIG. 19 illustrates an example of a connection area of the PN main terminal; and

FIG. 20 illustrates the evaluation of the PN main terminal according to the present embodiment.

### DETAILED DESCRIPTION OF THE INVENTION

Hereinafter, an embodiment will be described with reference to the accompanying drawings. In the following description, the terms “front surface” and “upper surface” refer to an X-Y plane facing up (in the +Z direction) in a semiconductor device illustrated in drawings. Similarly, the term “up” refers to an upward direction (the +Z direction) in the semiconductor device illustrated in the drawings. The terms “rear surface” and “lower surface” refer to an X-Y plane facing down (in the −Z direction) in the semiconductor device illustrated in the drawings. Similarly, the term “down” refers to a downward direction (the −Z direction) in the semiconductor device illustrated in the drawings. The same directionality applies to the other drawings, as appropriate. The terms “front surface,” “upper surface,” “up,” “rear surface,” “lower surface,” “down,” and “side surface” are used for convenience to describe relative positional relationships, and do not limit the technical concept of the embodiment. For example, the terms “up” and “down” are not always related to the vertical directions to the ground. That is, the “up” and “down” directions are not limited to the gravity direction.

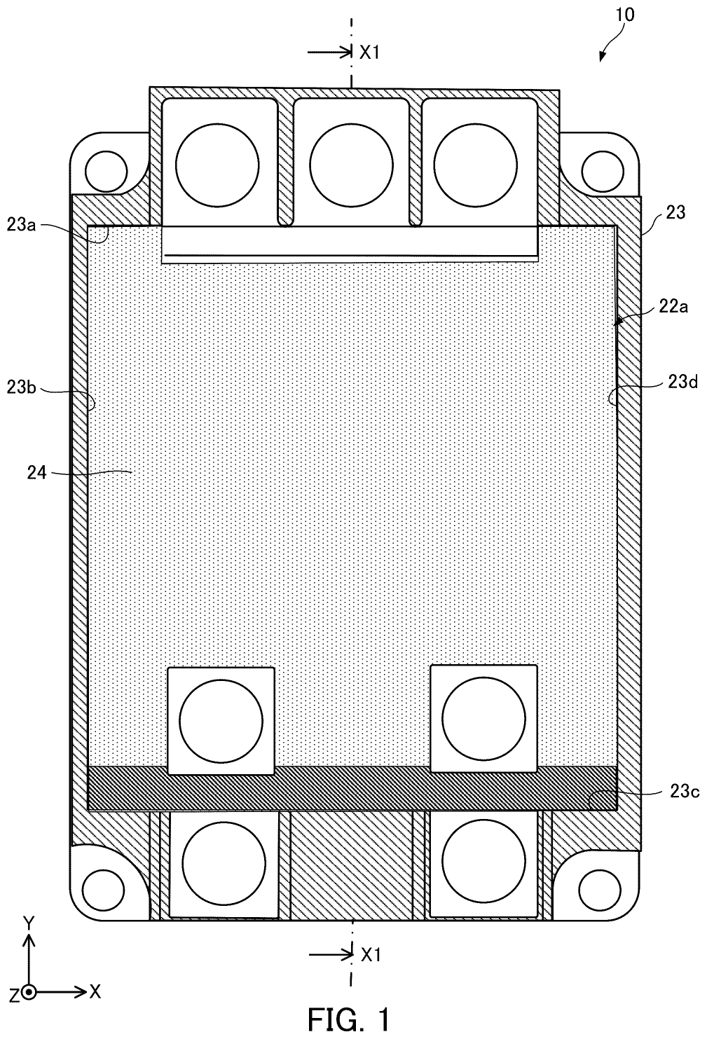

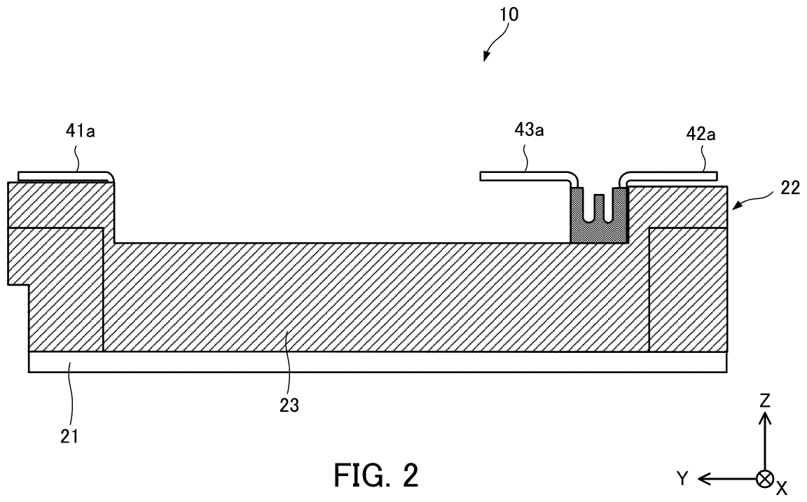

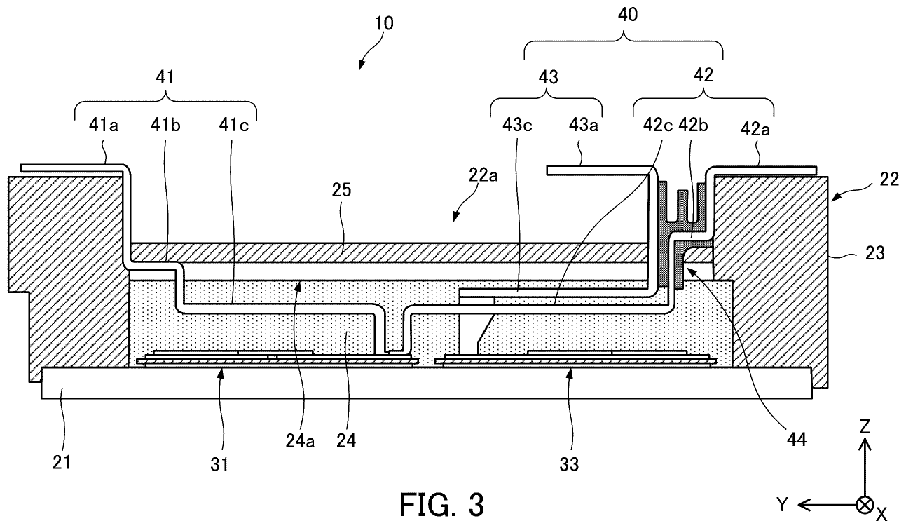

A semiconductor device will be described with reference to FIGS. 1 to 3. FIG. 1 is a first plan view of the semiconductor device. FIG. 2 is a side view of the semiconductor device. FIG. 3 is a sectional view of the semiconductor device. In this connection, FIG. 3 is a sectional view taken along a dash-dotted line X1-X1 of FIG. 1. In addition, wires are not illustrated in FIG. 3.

The semiconductor device 10 includes a heat dissipation plate 21 serving as the rear surface thereof, and a case 22 disposed on the heat dissipation plate 21 to serve as the side surfaces thereof. In addition, in the semiconductor device 10, components are housed in a housing space 22a surrounded by the heat dissipation plate 21 and case 22, and the components in the housing space 22a are sealed by a sealing material 24. The components housed in the housing space 22a include insulated circuit substrates, semiconductor chips disposed on the insulated circuit substrates, wires connecting these, and others. FIG. 3 illustrates insulated circuit substrates 31 and 33 as some of the insulated circuit substrates. In addition, the semiconductor device 10 includes an external connection output terminal 41, and an external connection main terminal 40 including a main terminal 42 (first main terminal) and a main terminal 43 (second main terminal).

The heat dissipation plate 21 is a plate-shaped member that is rectangular in plan view. The outer shape of the heat dissipation plate 21 may be one size smaller than the outer shape of the case 22. The corners of the heat dissipation plate 21 may be rounded or chamfered. The heat dissipation plate 21 is made of a metal with high heat dissipation. Examples of the metal here include copper, aluminum, and an alloy containing at least one of these. The surface of the heat dissipation plate 21 may be plated to improve its corrosion resistance. Examples of the plating material used here include nickel, a nickel-phosphorus alloy, and a nickel-boron alloy.

The insulated circuit substrates are bonded to the front surface of the heat dissipation plate 21 via a bonding material such as solder. Each insulated circuit substrate includes an insulating plate, circuit patterns formed on the front surface of the insulating plate, and a metal plate formed on the rear surface of the insulating plate.

The insulating plate is rectangular in plan view. The corners of the insulating plate may be rounded or chamfered. The insulating plate is made of ceramics with high thermal conductivity. For example, the ceramics here contain a material such as aluminum oxide, silicon nitride, or aluminum nitride as the main component thereof.

The circuit patterns are made of a metal with high electrical conductivity. Examples of the metal here include copper, aluminum, and an alloy containing at least one of these. The surfaces of the circuit patterns may be plated to improve their corrosion resistance. Examples of the plating material used here include nickel, a nickel-phosphorus alloy, and a nickel-boron alloy. In addition, the semiconductor chips, external connection output terminal 41, and main terminals 42 and 43 are mechanically and electrically connected to the circuit patterns where appropriate. In this connection, the configuration of the circuit patterns and semiconductor chips will be described later.

The metal plate is made of a metal with high thermal conductivity as its main component. Examples of the metal here include copper, aluminum, and an alloy containing at least one of these. The surface of the metal plate may be plated to improve its corrosion resistance. Examples of the plating material used here include nickel, a nickel-phosphorus alloy, and a nickel-boron alloy.

As each insulated circuit substrate with the above components, a direct copper bonding (DCB) substrate or an active metal brazed (AMB) substrate may be used, for example. In addition, the semiconductor chips, external connection output terminal 41, and main terminals 42 and 43 are bonded to the circuit patterns of the insulated circuit substrates via solder. Alternatively, the external connection output terminal 41 and main terminals 42 and 43 may be joined to the circuit patterns of the insulated circuit substrates by laser welding or ultrasonic welding. Lead-free solder is used as the solder. For example, the lead-free solder contains, as its main component, at least one of a tin-silver-copper alloy, a tin-zinc-bismuth alloy, a tin-copper alloy, and a tin-silver-indium-bismuth alloy. Instead of the solder, a sintered metal may be used. The material of the sintered metal is silver, gold, nickel, copper, or an alloy containing at least one of these.

In addition, for the insulated circuit substrates having the semiconductor chips disposed thereon, wires are used to make mechanical and electrical connections between the semiconductor chips, between the semiconductor chips and the circuit patterns, and between the plurality of circuit patterns. The wires are made of a material with high electrical conductivity. Examples of the material here include gold, silver, copper, aluminum, and an alloy containing at least one of these. For example, wires with a diameter of 20 μm to 300 μm, inclusive, are used for the control electrodes of the semiconductor chips. In addition, for example, wires with a diameter of 350 μm to 500 μm, inclusive, are used to connect to the main electrodes of the semiconductor chips for main current wiring.

The semiconductor chips may be made of silicon as its main component. The semiconductor chips may include reverse conducting-insulated gate bipolar transistors (RC-IGBTs), which have both an IGBT function and a free-wheeling diode (FWD) function. A semiconductor chip of this type has a collector electrode as an input electrode on the rear surface thereof, and has a gate electrode as a control electrode and an emitter electrode as an output electrode on the front surface thereof.

The present embodiment describes the case where the semiconductor chips are RC-IGBTs, as an example. Note, however, that the semiconductor chips may be made of silicon carbide as its main component. In this case, the semiconductor chips may be, for example, power metal-oxide-semiconductor field-effect transistors (MOSFETs), and each have an FWD together with a power MOSFET. A semiconductor chip of this type has a drain electrode as an input electrode on the rear surface thereof, and has a gate electrode as a control electrode and a source electrode as an output electrode on the front surface thereof. The semiconductor chips are bonded to predetermined circuit patterns of the insulated circuit substrates via a bonding material. The bonding material may be solder, as described earlier, or a sintered metal. For example, the sintered metal may contain aluminum, copper, or an alloy containing at least one of these as its main component.

The case 22 includes a side wall portion 23 and a lid 25 covering the lower part of the side wall portion 23. FIG. 1 is a plan view without the lid 25. The inner surfaces of the side wall portion 23 form a rectangle in plan view. The side wall portion 23 includes first to fourth inner wall surfaces 23a to 23d that surround the four sides of the housing space 22a. The first and third inner wall surfaces 23a and 23c correspond to the short sides, whereas the second and fourth inner wall surfaces 23b and 23d correspond to the long sides. The lower surface of the side wall portion 23 is bonded to the outer edge of the heat dissipation plate 21 by an adhesive or the like.

The case 22 is formed using a thermoplastic resin by integrally insert-molding the external connection output terminal 41 and the main terminals 42 and 43 into the side wall portion 23 and the lid 25. Examples of the resin here include a polyphenylene sulfide resin, a polybutylene terephthalate resin, a polybutylene succinate resin, a polyamide resin, and an acrylonitrile butadiene styrene resin.

The housing space 22a surrounded by the heat dissipation plate 21 and the side wall portion 23 of the case 22 is filled with the sealing material 24. Thereby, the components disposed in the housing space 22a, including the insulated circuit substrates, circuit patterns, semiconductor chips, wires, and others are sealed by the sealing material 24. The sealing material is an insulating polymer gel, and preferably contains a silicone gel as its main component.

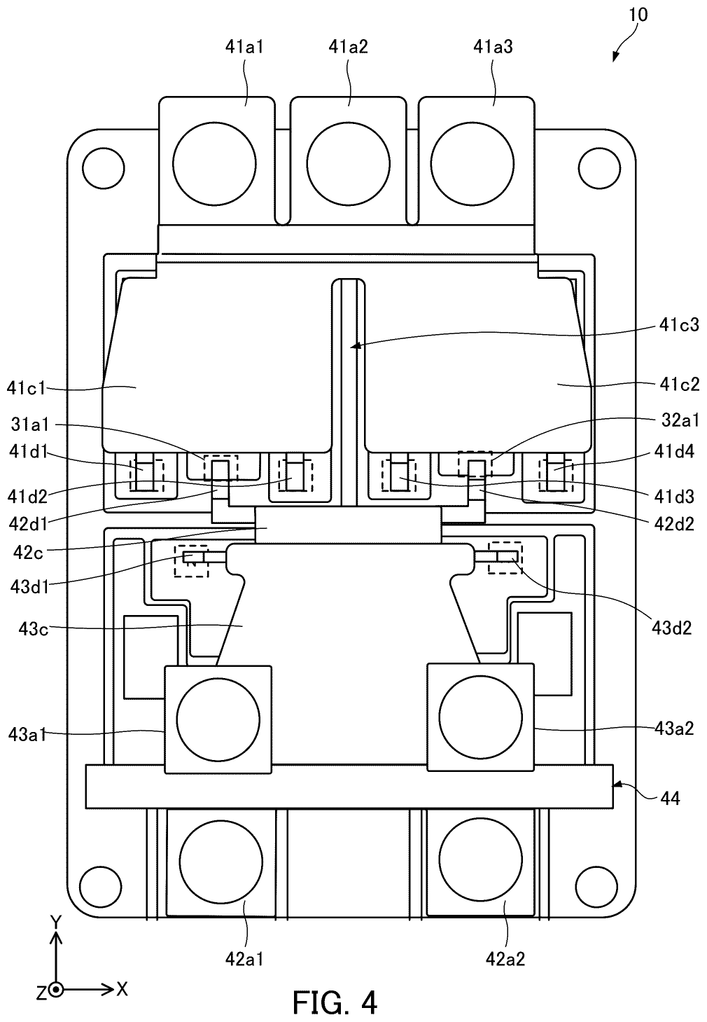

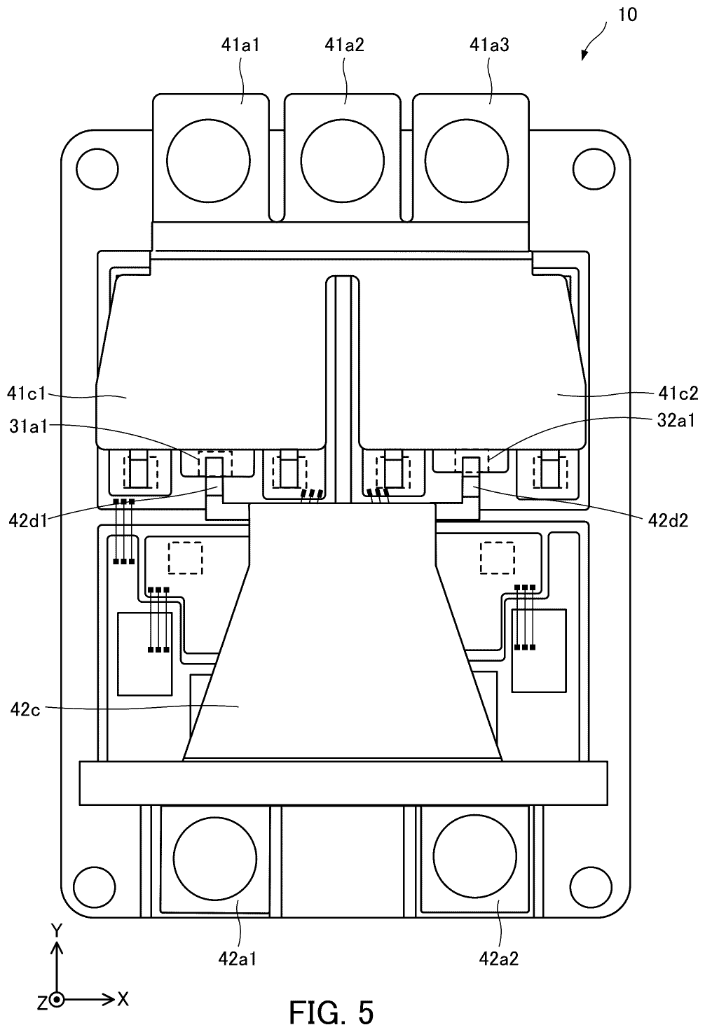

FIG. 4 illustrates a second plan view of the semiconductor device. FIG. 5 is a third plan view of the semiconductor device. In this connection, FIG. 4 is the first plan view of FIG. 1 with the sealing material 24 in the housing space 22a of the case 22 removed. The wires are also not illustrated in FIG. 4. FIG. 5 is the second plan view of FIG. 4 with the main terminal 43 removed. The following describes the external connection output terminal 41 and main terminals 42 and 43 with reference to FIGS. 3 to 5.

The external connection output terminal 41 and main terminals 42 and 43 electrically connect the circuit patterns and external devices. Each of the external connection output terminal 41 and main terminals 42 and 43 is formed of a flat plate-shaped electrically conductive member. In this connection, a part of the main terminal 42 and a part of the main terminal 43 are integrally held by a terminal holding portion 44.

One end of the external connection output terminal 41 is exposed from the upper surface of the lid 25 of the case 22 and serves as an external output terminal 41a that connects to an external device. The external connection output terminal 41 includes the external output terminal 41a, a horizontal portion 41b, and a horizontal portion 41c, arranged in this order from the one end toward the other. The horizontal portions 41b and 41c are horizontal to the bottom surface of the housing space 22a. The height of the horizontal portion 41b is lower than that of the external output terminal 41a, and the height of the horizontal portion 41c is lower than that of the horizontal portion 41b. For example, the external output terminal 41a and horizontal portions 41b and 41c are formed by bending the flat plate-shaped external connection output terminal 41 such that the external output terminal 41a and the horizontal portion 41b are connected by a vertically extending connecting portion and the horizontal portions 41b and 41c are likewise connected by a vertically extending connecting portion.

The external output terminal 41a is divided into external output terminals 41a1 to 41a3 in the horizontal direction (X direction). In addition, the horizontal portion 41c is divided into horizontal portions 41c1 and 41c2 in the horizontal direction (X direction) with a central slit 41c3 extending therebetween. Furthermore, connection terminals 41d1 and 41d2 are formed at an edge of the horizontal portion 41c1 to extend downward therefrom. The connection terminals 41d1 and 41d2 are electrically and mechanically connected respectively to circuit patterns 31b and 31c (to be described later) via solder. In addition, connection terminals 41d3 and 41d4 are formed at an edge of the horizontal portion 41c2 to extend downward therefrom. The connection terminals 41d3 and 41d4 are electrically and mechanically connected respectively to circuit patterns 32b and 32c (to be described later) via solder. Alternatively, they may be directly connected by laser welding or ultrasonic welding, for example.

On the other hand, one end of the main terminal 42 is exposed from the upper surface of the lid 25 of the case 22 and serves as an external terminal 42a that connects to an external device (external power supply). The main terminal 42 includes the external terminal 42a, a horizontal portion 42b, and a horizontal portion 42c, arranged in this order from the one end toward the other. The horizontal portions 42b and 42c are horizontal to the bottom surface of the housing space 22a. The height of the horizontal portion 42b is lower than that of the external terminal 42a, and the height of the horizontal portion 42c is lower than that of the horizontal portion 42b. The external terminal 42a and horizontal portions 42b and 42c are formed by bending the flat plate-shaped main terminal 42 such that the external terminal 42a and the horizontal portion 42b are connected by a vertically extending connecting portion and the horizontal portions 42b and 42c are likewise connected by a vertically extending connecting portion.

The external terminal 42a is divided into external terminals 42a1 and 42a2 in the horizontal direction (X direction). Furthermore, connection terminals 42d1 and 42d2 are formed at edges of the horizontal portion 42c to extend downward therefrom. The connection terminals 42d1 and 42d2 are electrically and mechanically connected respectively to circuit patterns 31a and 32a (to be described later) via solder. Alternatively, they may be directly connected by laser welding or ultrasonic welding, for example.

One end of the main terminal 43 is exposed above the upper surface of the lid 25 of the case 22 and serves as an external terminal 43a that connects to the external device. The external terminal 43a is divided into external terminals 43a1 and 43a2 in the horizontal direction (X direction). In addition, the main terminal 43 includes the external terminal 43a and a horizontal portion 43c, arranged in this order from the one end toward the other. The horizontal portion 43c is horizontal to the bottom surface of the housing space 22a. The height of the horizontal portion 43c is lower than that of the external terminal 43a. The external terminal 43a and horizontal portion 43c are formed by bending the flat plate-shaped main terminal 43 such that the external terminal 43a and the horizontal portion 43c are connected by a vertically extending connecting portion.

In addition, connection terminals 43d1 and 43d2 are formed at edges of the horizontal portion 43c to extend downward therefrom. The connection terminals 43d1 and 43d2 are electrically and mechanically connected respectively to circuit patterns 33b and 34b (to be described later) via solder. Alternatively, they may be directly connected by laser welding or ultrasonic welding, for example.

The terminal holding portion 44 seals the connecting portion that connects the external terminal 43a and horizontal portion 43c of the main terminal 43, the connecting portion that connect the external terminal 42a and horizontal portion 42b of the main terminal 42, the connecting portion that connect the horizontal portions 42b and 42c of the main terminal 42, and the horizontal portion 42b. This sealing makes it possible to maintain insulation even in the case where the main terminals 42 and 43 are placed close to each other. The terminal holding portion 44 may be made of the same material as the case 22.

Although not illustrated, a control terminal may also be provided. In this case, one end of the control terminal is exposed from the case 22 or the lid 25 of the case 22, and the other end thereof is positioned inside the housing space 22a. The other end of the control terminal is electrically connected to the control electrode of a semiconductor chip. The other end of the control terminal may be mechanically and electrically connected to the control electrode of the semiconductor chip with a control wire. The other end of the control terminal and the control wire may be mechanically and electrically connected via a circuit pattern. In addition, the diameter of the control wire may be smaller than that of a wire used for main current wiring.

The horizontal portion 41c of the external connection output terminal 41, the horizontal portion 42c of the main terminal 42, and the horizontal portion 43c of the main terminal 43 are placed below the upper surface 24a of the sealing material 24 and are therefore sealed by the sealing material 24.

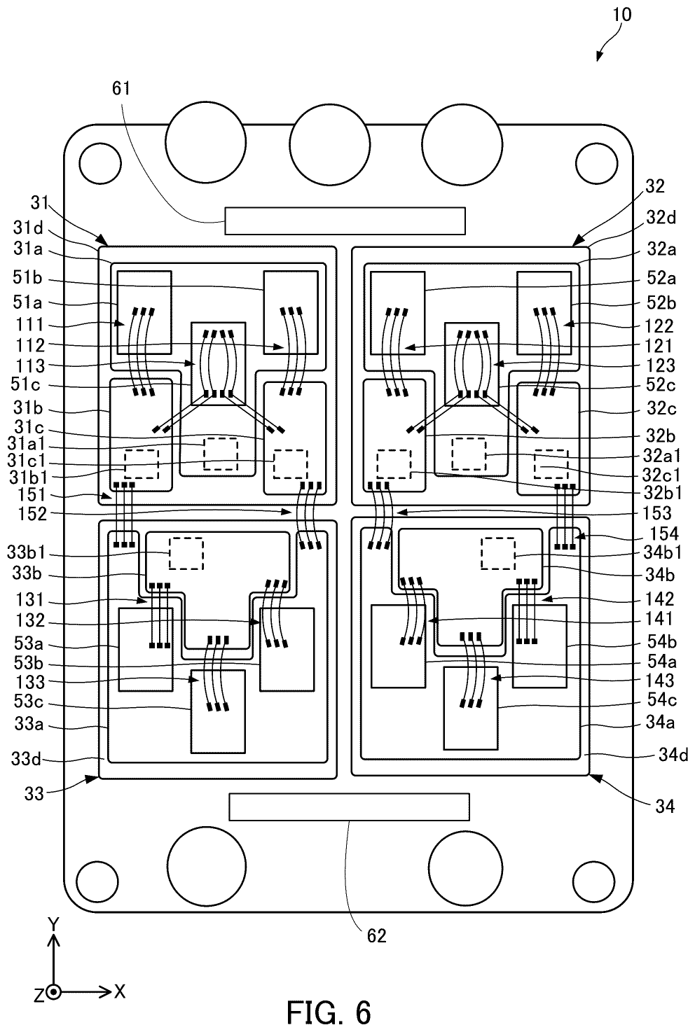

FIG. 6 is a fourth plan view of the semiconductor device. In this connection, FIG. 6 is the third plan view of FIG. 5 with the external connection output terminal 41 and main terminal 42 removed. The following describes the configuration of the insulated circuit substrates, semiconductor chips, and wires with reference to FIG. 6.

An insulated circuit substrate group is bonded to the front surface of the heat dissipation plate 21. The insulated circuit substrate group includes an insulated circuit substrate 31 (first insulated circuit substrate), an insulated circuit substrate 32 (second insulated circuit substrate), an insulated circuit substrate 33 (third insulated circuit substrate), and an insulated circuit substrate 34 (fourth insulated circuit substrate). Auxiliary substrates 61 and 62 are further bonded to the front surface of the heat dissipation plate 21. The auxiliary substrate 61 is provided in the vicinity of the short side of the device located in the +Y direction with respect to the insulated circuit substrates 31 and 32, and a lead to be connected to the insulated circuit substrates 31 and 32 is formed by patterning. In addition, the auxiliary substrate 62 is provided in the vicinity of the short side of the device located in the −Y direction with respect to the insulated circuit substrates 33 and 34, and a lead to be connected to the insulated circuit substrates 33 and 34 is formed by patterning. In this connection, each auxiliary substrate 61 and 62 may include a circuit pattern that is connected to a control terminal to control inputs to the gate electrodes of semiconductor chips, a circuit pattern that is connected to an auxiliary emitter terminal, and others, for example.

Circuit patterns 31a to 31c are formed on the front surface of an insulating plate 31d included in the insulated circuit substrate 31. Circuit patterns 32a to 32c are formed on the front surface of an insulating plate 32d included in the insulated circuit substrate 32. Circuit patterns 33a and 33b are formed on the front surface of an insulating plate 33d included in the insulated circuit substrate 33. Circuit patterns 34a and 34b are formed on the front surface of an insulating plate 34d included in the insulated circuit substrate 34.

The circuit pattern 31a is T-shaped in plan view. The circuit pattern 31a is provided close to the end in the +Y direction of the insulating plate 31d. Semiconductor chips 51a to 51c are disposed on the circuit pattern 31a. The semiconductor chips 51a and 51b are disposed on opposite sides in the +X directions on the circuit pattern 31a. The semiconductor chip 51c is disposed in the middle between the semiconductor chips 51a and 51b on the circuit pattern 31a. The rear surfaces of the semiconductor chips 51a to 51c are mechanically and electrically bonded to the circuit pattern 31a via solder, which is a bonding material.

The circuit patterns 31b and 31c are rectangular in plan view. The circuit patterns 31b and 31c are disposed on both sides of the projecting part of the circuit pattern 31a projecting in the −Y direction, on the insulating plate 31d. The output electrode on the front surface of the semiconductor chip 51a and the circuit pattern 31b are mechanically and electrically connected to each other with wires 111. The output electrode on the front surface of the semiconductor chip 51b and the circuit pattern 31c are mechanically and electrically connected to each other with wires 112. The output electrode on the front surface of the semiconductor chip 51c and each of the circuit patterns 31b and 31c are mechanically and electrically connected to each other with wires 113.

The circuit patterns 31b and 33a are mechanically and electrically connected to each other with wires 151. The circuit patterns 31c and 33a are mechanically and electrically connected to each other with wires 152.

In addition, the connection terminal 42d1 of the main terminal 42 is electrically and mechanically connected to a region 31a1 of the circuit pattern 31a by solder, ultrasonic bonding, or another. The connection terminal 41d1 of the external connection output terminal 41 is electrically and mechanically connected to a region 31b1 of the circuit pattern 31b by solder. The connection terminal 41d2 of the external connection output terminal 41 is electrically and mechanically connected to a region 31c1 of the circuit pattern 31c by solder.

The circuit pattern 32a is T-shaped in plan view. The circuit pattern 32a is provided close to the end in the +Y direction of the insulating plate 32d. Semiconductor chips 52a to 52c are disposed on the circuit pattern 32a. The semiconductor chips 52a and 52b are disposed on opposite sides in the #X directions on the circuit pattern 32a. The semiconductor chip 52c is disposed in the middle between the semiconductor chips 52a and 52b on the circuit pattern 32a. The rear surfaces of the semiconductor chips 52a to 52c are mechanically and electrically bonded to the circuit pattern 32a via solder, which is a bonding material.

The circuit patterns 32b and 32c are rectangular in plan view. The circuit patterns 32b and 32c are disposed on both sides of the projecting part of the circuit pattern 32a projecting in the −Y direction, on the insulating plate 32d. The output electrode on the front surface of the semiconductor chip 52a and the circuit pattern 32b are mechanically and electrically connected to each other with wires 121. The output electrode on the front surface of the semiconductor chip 52b and the circuit pattern 32c are mechanically and electrically connected to each other with wires 122. The output electrode on the front surface of the semiconductor chip 52c and each of the circuit patterns 32b and 32c are mechanically and electrically connected to each other with wires 123.

The circuit patterns 32b and 34a are mechanically and electrically connected to each other with wires 153. The circuit patterns 32c and 34a are mechanically and electrically connected to each other with wires 154.

In addition, the connection terminal 42d2 of the main terminal 42 is electrically and mechanically connected to a region 32a1 of the circuit pattern 32a by solder, ultrasonic bonding, or another. The connection terminal 41d3 of the external connection output terminal 41 is electrically and mechanically connected to a region 32b1 of the circuit pattern 32b by solder. The connection terminal 41d4 of the external connection output terminal 41 is electrically and mechanically connected to a region 32c1 of the circuit pattern 32c by solder.

The circuit pattern 33a is U-shaped in plan view. The circuit pattern 33a is provided close to the end in the −Y direction of the insulating plate 33d. Semiconductor chips 53a to 53c are disposed on the circuit pattern 33a. The semiconductor chips 53a and 53b are disposed on opposite sides of the circuit pattern 33a, with the recess of the circuit pattern 33a therebetween. The semiconductor chip 53c is disposed in the center close to the end in −Y direction of the circuit pattern 33a between the semiconductor chips 53a and 53b. The rear surfaces of the semiconductor chips 53a to 53c are mechanically and electrically bonded to the circuit pattern 33a by solder, which is a bonding material.

The circuit pattern 33b is T-shaped in plan view, and is formed close to the end in the +Y direction of the insulating plate 33d within the recess of the circuit pattern The output electrode on the front surface of the 33a. The semiconductor chip 53a and the circuit pattern 33b are mechanically and electrically connected to each other with wires 131. The output electrode on the front surface of the semiconductor chip 53b and the circuit pattern 33b are mechanically and electrically connected to each other with wires 132. The output electrode on the front surface of the semiconductor chip 53c and the circuit pattern 33b are mechanically and electrically connected to each other with wires 133.

The circuit pattern 34a is U-shaped in plan view. The circuit pattern 34a is provided close to the end in the −Y direction of the insulating plate 34d. Semiconductor chips 54a to 54c are disposed on the circuit pattern 34a. The semiconductor chips 54a and 54b are disposed on opposite sides of the circuit pattern 34a, with the recess of the circuit pattern 34a therebetween. The semiconductor chip 54c is disposed in the center close to the end in the −Y direction of the circuit pattern 34a between the semiconductor chips 54a and 54b. The rear surfaces of the semiconductor chips 54a to 54c are mechanically and electrically bonded to the circuit pattern 34a by solder.

The circuit pattern 34b is T-shaped in plan view, and is formed close to the end in +Y direction of the insulating plate 34d within the recess of the circuit pattern 34a. The output electrode on the front surface of the semiconductor chip 54a and the circuit pattern 34b are mechanically and electrically connected to each other with wires 141. The output electrode on the front surface of the semiconductor chip 54b and the circuit pattern 34b are mechanically and electrically connected to each other with wires 142. The output electrode on the front surface of the semiconductor chip 54c and the circuit pattern 34b are mechanically and electrically connected to each other with wires 143.

In addition, the connection terminal 43d1 of the main terminal 43 is electrically and mechanically connected to a region 33b1 of the circuit pattern 33b by solder, ultrasonic bonding, or another. The connection terminal 43d2 of the main terminal 43 is electrically and mechanically connected to a region 34b1 of the circuit pattern 34b by solder, ultrasonic bonding, or another.

The above-mentioned wires 111 to 113, 121 to 123, 131 to 133, 141 to 143, and 151 to 154 are bonding wires made of a metal with high electrical conductivity as its main component. The metal here is aluminum, copper, or an alloy containing at least one of these. In the present embodiment, the wires 111 to 113, 121 to 123, 131 to 133, 141 to 143, and 151 to 154 are used for main current wiring, and for example, have a diameter of 300 μm to 500 μm, inclusive.

In this connection, the wires 111 to 113, 121 to 123, 131 to 133, 141 to 143, and 151 to 154 may be bonded to conductive portions (circuit patterns and output electrodes on the front surfaces of semiconductor chips) using a bonding device. Each wire 111 to 113, 121 to 123, 131 to 133, 141 to 143, and 151 to 154 is subjected to ultrasonic vibrations while being pressed against the corresponding conductive portion by the bonding tool of the bonding device. Through such wedge bonding, the wires 111 to 113, 121 to 123, 131 to 133, 141 to 143, and 151 to 154 are bonded to the conductive portions.

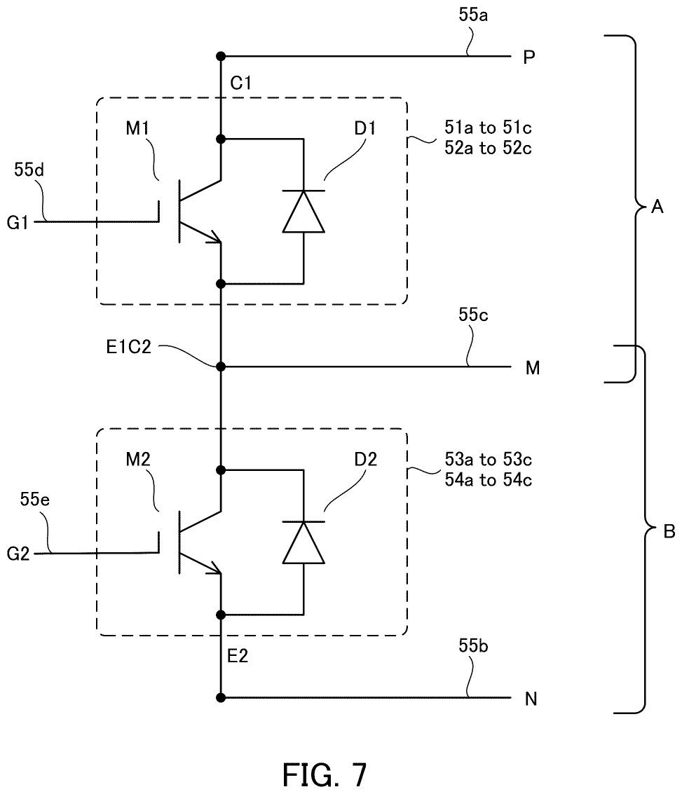

In addition, each semiconductor chip 51a to 51c, 52a to 52c, 53a to 53c, and 54a to 54c is an RC-IGBT, which has both the IGBT and FWD functions, as described earlier. The following describes a power conversion function of the semiconductor device 10 with reference to FIG. 7.

FIG. 7 illustrates an equivalent circuit modeling the function of the semiconductor device. FIG. 7 illustrates an inverter circuit formed of the semiconductor chips 51a to 51c and 52a to 52c and the semiconductor chips 53a to 53c and 54a to 54c, which each include an RC-IGBT. Each semiconductor chip 51a to 51c and 52a to 52c includes a switching element (IGBT) M1 and a diode element (FWD) D1. Each semiconductor chip 53a to 53c and 54a to 54c includes a switching element (IGBT) M2 and a diode element (FWD) D2.

The semiconductor device 10 forms a half-bridge circuit including an upper arm portion A and a lower arm portion B. The upper arm portion A of the semiconductor device 10 includes the wires 111 to 113, wires 121 to 123, semiconductor chips 51a to 51c, semiconductor chips 52a to 52c, and main terminal 42, which are arranged on the insulated circuit substrates 31 and 32. The upper arm portion A also includes the external connection output terminal 41, which is arranged on the circuit patterns 31b and 31c of the insulated circuit substrate 31 and the circuit patterns 32b and 32c of the insulated circuit substrate 32.

The lower arm portion B of the semiconductor device 10 includes the wires 131 to 133, wires 141 to 143, semiconductor chips 53a to 53c, semiconductor chips 54a to 54c, and main terminal 43, which are arranged on the insulated circuit substrates 33 and 34.

The insulated circuit substrate 31 and the insulated circuit substrate 33 are connected to each other by the wires 151 and 152, and the insulated circuit substrate 32 and the insulated circuit substrate 34 are connected to each other by the wires 153 and 154. By doing so, the upper arm portion A and the lower arm portion B are connected to each other. As a result, the semiconductor device 10 is able to function as the half-bridge circuit including the upper arm portion A and the lower arm portion B.

In this case, in the semiconductor device 10, a wiring 55a connecting a connection point P that is connected to the positive electrode of an external power supply (not illustrated) and a connection point C1 of the input electrodes (collector electrodes) on the rear surfaces of the semiconductor chips 51a to 51c and 52a to 52c corresponds to the main terminal 42 and circuit patterns 31a and 32a. In other words, the main terminal 42 serves as a P main terminal that forms a positive input terminal in the half-bridge circuit.

A wiring 55c connecting a connection point M that is connected to the terminal of a load (not illustrated) and a connection point E1C2 of the output electrodes (emitter electrodes) of the semiconductor chips 51a to 51c and 52a to 52c and the input electrodes (collector electrodes) of the semiconductor chips 53a to 53c and 54a to 54c corresponds to the external connection output terminal 41, circuit patterns 31b and 31c, circuit patterns 32b and 32c, wires 151 and 152, wires 153 and 154, and circuit patterns 33a and 34a. In other words, the external connection output terminal 41 serves as an M terminal that forms an output terminal in the half-bridge circuit.

A wiring 55b connecting a connection point N that is connected to the negative electrode of the external power supply and a connection point E2 of the output electrodes (emitter electrodes) of the semiconductor chips 53a to 53c and 54a to 54c corresponds to the main terminal 43 and circuit patterns 33b and 34b. In other words, the main terminal 43 serves as an N main terminal that forms a negative input terminal in the half-bridge circuit.

Furthermore, wirings 55d and 55e connecting the connection points G1 and G2, to which control signals are input, to the control electrodes (gate electrodes) of the semiconductor chips 51a to 51c and 52a to 52c and the semiconductor chips 53a to 53c and 54a to 54c, respectively, correspond to control terminals, not illustrated.

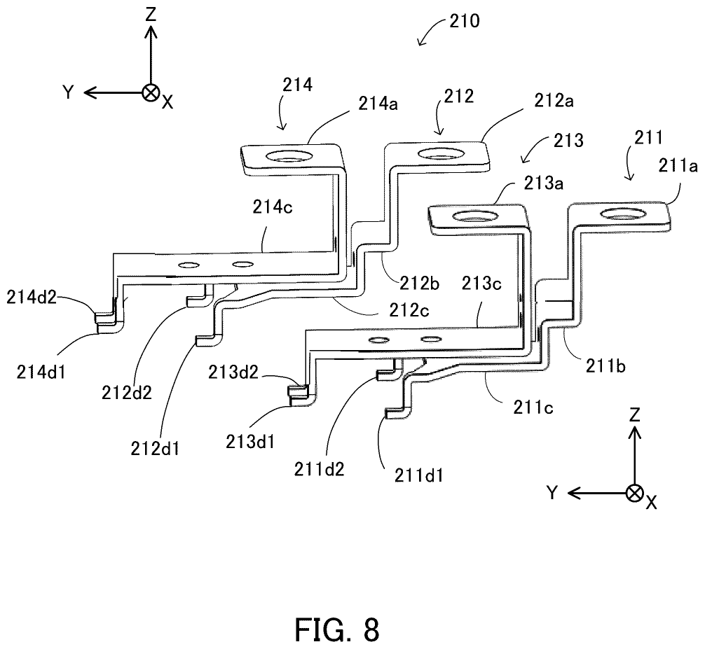

The following describes a P main terminal and an N main terminal (hereinafter, the P main terminal and the N main terminal may collectively be referred to as a PN main terminal) that are external connection main terminals in reference examples, with reference to FIGS. 8 to 11.

FIG. 8 illustrates the configuration of a PN main terminal according to a first reference example. The PN main terminal 210 has a pair structure formed of a P main terminal 211 and an N main terminal 213 and a pair structure formed of a P main terminal 212 and an N main terminal 214. Note that the illustration of a terminal holding portion, which maintains the insulation between the P main terminal 211 and the N main terminal 213 and the insulation between the P main terminal 212 and the N main terminal 214, is omitted.

One end of the P main terminal 211 is exposed on the upper surface of a case and serves as an external terminal 211a that connects to an external device. The P main terminal 211 includes the external terminal 211a, a horizontal portion 211b, and a horizontal portion 211c, arranged in this order from the one end toward the other. The horizontal portions 211b and 211c are horizontal (in the Y direction) to the bottom surface of a device housing space. The height of the horizontal portion 211b is lower than that of the external terminal 211a, and the height of the horizontal portion 211c is lower than the horizontal portion 211b. The external terminal 211a and horizontal portions 211b and 211c are formed by bending the flat plate-shaped P main terminal 211 such that the external terminal 211a and the horizontal portion 211b are connected by a vertically extending connecting portion and the horizontal portions 211b and 211c are likewise connected by a vertically extending connecting portion. In addition, connection terminals 211d1 and 211d2 are formed at an edge of the horizontal portion 211c to extend vertically therefrom toward an insulated circuit substrate.

In addition, the N main terminal 213 is placed over the P main terminal 211, and one end of the N main terminal 213 is exposed above the upper surface of the case and serves as an external terminal 213a that connects to the external device. The N main terminal 213 includes the external terminal 213a and a horizontal portion 213c, arranged in this order from the one end toward the other. The horizontal portion 213c is horizontal to the bottom surface of the device housing space, and the height of the horizontal portion 213c is lower than that of the external terminal 213a. Moreover, the horizontal portion 213c is formed to be longer in the +Y direction than the horizontal portion 211c of the P main terminal 211, and is placed to form an overlapping area where the horizontal portion 213c is superimposed on the horizontal portion 211c with a predetermined distance therebetween (hereinafter, such an overlapping area may be referred to as a laminated portion).

The external terminal 213a and the horizontal portion 213c are formed by bending the flat plate-shaped N main terminal 213 such that the external terminal 213a and the horizontal portion 213c are connected by a vertically extending connecting portion. In addition, connection terminals 213d1 and 213d2 are formed at an edge of the horizontal portion 213c to extend vertically therefrom toward an insulated circuit substrate.

Each of the connection terminals 211d1 and 211d2 of the P main terminal 211 and the connection terminals 213d1 and 213d2 of the N main terminal 213 is electrically and mechanically connected to a circuit pattern via solder. Alternatively, they may be directly connected by laser welding or ultrasonic welding, for example.

On the other hand, one end of the P main terminal 212 is exposed on the upper surface of the case and serves as an external terminal 212a that connects to the external device. The P main terminal 212 includes the external terminal 212a, a horizontal portion 212b, and a horizontal portion 212c, arranged in this order from the one end toward the other. The horizontal portions 212b and 212c are horizontal to the bottom surface of the device housing space, the height of the horizontal portion 212b is lower than that of the external terminal 212a, and the height of the horizontal portion 212c is lower than that of horizontal portion 212b. The external terminal 212a and horizontal portions 212b and 212c are formed by bending the flat plate-shaped P main terminal 212 such that the external terminal 212a and the horizontal portion 212b are connected by a vertically extending connecting portion and the horizontal portions 212b and 212c are likewise connected by a vertically extending connecting portion. In addition, connection terminals 212d1 and 212d2 are formed at an edge of the horizontal portion 212c to extend vertically therefrom toward an insulated circuit substrate.

In addition, the N main terminal 214 is placed over the P main terminal 212, and one end of the N main terminal 214 is exposed above the upper surface of the case and serves as an external terminal 214a that connects to the external device. The N main terminal 214 includes the external terminal 214a and a horizontal portion 214c, arranged in this order from the one end toward the other. The horizontal portion 214c is horizontal to the bottom surface of the device housing space, and the height of the horizontal portion 214c is lower than that of the external terminal 214a. Furthermore, the horizontal portion 214c is formed to be longer in the +Y direction than the horizontal portion 212c of the P main terminal 212, and is placed to form a laminated portion where the horizontal portion 214c is superimposed on the horizontal portion 212c with a predetermined distance therebetween.

The external terminal 214a and the horizontal portion 214c are formed by bending the flat plate-shaped N main terminal 214 such that the external terminal 214a and the horizontal portion 214c are connected by a vertically extending connecting portion. In addition, connection terminals 214d1 and 214d2 are formed at an edge of the horizontal portion 214c to extend vertically therefrom toward an insulated circuit substrate.

Each of the connection terminals 212d1 and 212d2 of the P main terminal 212 and the connection terminals 214d1 and 214d2 of the N main terminal 214 is electrically and mechanically connected to a circuit pattern via solder. Alternatively, they may be directly connected by laser welding or ultrasonic welding, for example.

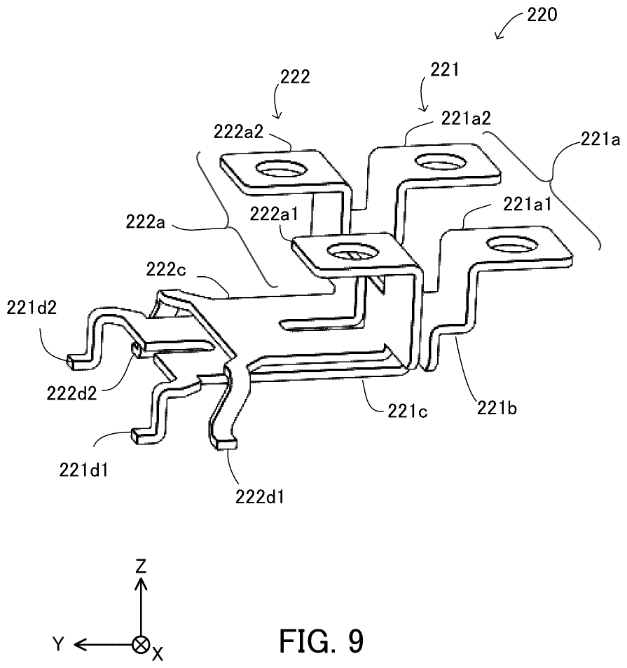

FIG. 9 illustrates the configuration of a PN main terminal according to a second reference example. The PN main terminal 220 includes a P main terminal 221 and an N main terminal 222. Note that the illustration of a terminal holding portion, which maintains the insulation between the P main terminal 221 and the N main terminal 222, is omitted.

One end of the P main terminal 221 is exposed on the upper surface of a case and serves as an external terminal 221a that connects to an external device. The external terminal 221a is divided into external terminals 221a1 and 221a2 in the horizontal direction (X direction). The P main terminal 221 includes the external terminal 221a, a horizontal portion 221b, and a horizontal portion 221c, arranged in this order from the one end toward the other.

The horizontal portions 221b and 221c are horizontal to the bottom surface of a device housing space. The height of the horizontal portion 221b is lower than that of the external terminal 221a, and the height of the horizontal portion 221c is lower than that of the horizontal portion 221b. The external terminal 221a and the horizontal portions 221b and 221c are formed by bending the flat plate-shaped P main terminal 221 such that the external terminal 221a and the horizontal portion 221b are connected by a vertically extending connecting portion and the horizontal portions 221b and 221c are likewise connected by a vertically extending connecting portion. In addition, connection terminals 221d1 and 221d2 are formed at an edge of the horizontal portion 221c to extend vertically therefrom toward insulated circuit substrates.

In addition, the N main terminal 222 is placed over the P main terminal 221, and one end of the N main terminal 222 is exposed above the upper surface of the case and serves as an external terminal 222a that connects to the external device. The external terminal 222a is divided into external terminals 222a1 and 222a2 in the horizontal direction. The N main terminal 222 includes the external terminal 222a and a horizontal portion 222c, arranged in this order from the one end toward the other. The horizontal portion 222c is horizontal to the bottom surface of the device housing space, and the height of the horizontal portion 222c is lower than that of the external terminal 222a but higher than that of the horizontal portion 221c of the P main terminal 221. Furthermore, the horizontal portion 222c is formed to be shorter in the −Y direction than the horizontal portion 221c of the P main terminal 221, and is placed to form a laminated portion where the horizontal portion 222c is superimposed on the horizontal portion 221c with a predetermined distance therebetween.

The external terminal 222a and the horizontal portion 222c are formed by bending the flat plate-shaped N main terminal 222 such that the external terminal 222a and the horizontal portion 222c are connected by a vertically extending connecting portion. In addition, connection terminals 222d1 and 222d2 are formed at an edge of the horizontal portion 222c to extend vertically therefrom toward insulated circuit substrates across the horizontal portion 221c.

Each of the connection terminals 221d1 and 221d2 of the P main terminal 221 and the connection terminals 222d1 and 222d2 of the N main terminal 222 is electrically and mechanically connected to a circuit pattern via solder. Alternatively, they may be directly connected by laser welding or ultrasonic welding, for example.

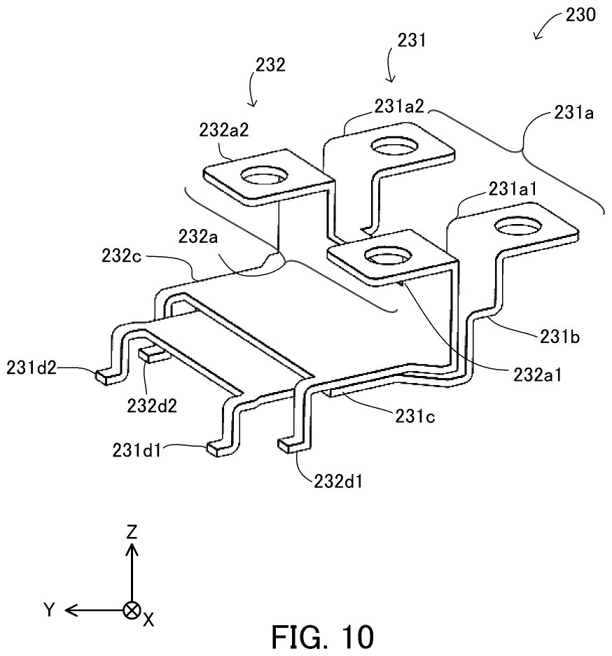

FIG. 10 illustrates the configuration of a PN main terminal according to a third reference example. The PN main terminal 230 includes a P main terminal 231 and an N main terminal 232. Note that the illustration of a terminal holding portion, which maintains the insulation between the P main terminal 231 and the N main terminal 232, is omitted.

One end of the P main terminal 231 is exposed on the upper surface of a case and serves as an external terminal 231a that connects to an external device. The external terminal 231a is divided into external terminals 231a1 and 231a2 in the horizontal direction (X direction). In addition, the P main terminal 231 includes the external terminal 231a, a horizontal portion 231b, and a horizontal portion 231c, arranged in this order from the one end toward the other. The horizontal portions 231b and 231c are horizontal to the bottom surface of a device housing space, the height of horizontal portion 231b is lower than that of the external terminal 231a, and the height of the horizontal portion 231c is lower than that of the horizontal portion 231b. The external terminal 231a and the horizontal portions 231b and 231c are formed by bending the flat plate-shaped P main terminal 231 such that the external terminal 231a and the horizontal portion 231b are connected by a vertically extending connecting portion and the horizontal portions 231b and 231c are likewise connected by a vertically extending connecting portion. In addition, connection terminals 231d1 and 231d2 are formed at an edge of the horizontal portion 231c to extend vertically therefrom toward insulated circuit substrates.

The N main terminal 232 is placed over the P main terminal 231, and one end of the N main terminal 232 is exposed above the upper surface of the case and serves as an external terminal 232a that connects to the external device. The external terminal 232a is divided into external terminals 232a1 and 232a2 in the horizontal direction. The N main terminal 232 includes the external terminal 232a and a horizontal portion 232c, arranged in this order from the one end toward the other. The horizontal portion 232c is horizontal to the bottom surface of the device housing space, and the height of the horizontal portion 232c is lower than that of the external terminal 232a but higher than that of the horizontal portion 231c of the P main terminal 231. Moreover, the horizontal portion 232c is formed to be shorter in the −Y direction than the horizontal portion 231c of the P main terminal 231, and is placed to form a laminated portion where the horizontal portion 232c is superimposed on the horizontal portion 231c with a predetermined distance therebetween.

The external terminal 232a and the horizontal portion 232c are formed by bending the flat plate-shaped N main terminal 232 such that the external terminal 232a and the horizontal portion 232c are connected by a vertically extending connecting portion. In addition, connection terminals 232d1 and 232d2 are formed at an edge of the horizontal portion 232c to extend vertically therefrom toward insulated circuit substrates across the horizontal portion 231c.

Each of the connection terminals 231d1 and 231d2 of the P main terminal 231 and the connection terminals 232d1 and 232d2 of the N main terminal 232 is electrically and mechanically connected to a circuit pattern via solder. Alternatively, they may be directly connected by laser welding or ultrasonic welding, for example.

In a semiconductor device, there is parasitic inductance (L component) in a conductor portion of a wiring pattern in an insulated circuit substrate. The parasitic inductance may decrease the switching speed of the switching element included in a semiconductor chip to thereby increase switching loss, and may cause voltage fluctuations between the power supply and the ground. Therefore, there is a demand to reduce the parasitic inductance.

In order to reduce such parasitic inductance, the PN main terminal 210 in the first reference example illustrated in FIG. 8 is configured so that the number of connection terminals that are connected to insulated circuit substrates is increased to eight. However, this approach of increasing the number of connection terminals for the connection between the PN main terminal 210 and the insulated circuit substrates to thereby reduce the parasitic inductance results in a shortage of space for mounting semiconductor chips and also makes it difficult to increase the current rating of the semiconductor device.

On the other hand, the PN main terminal 220 in the second reference example illustrated in FIG. 9 is configured so that the number of connection terminals that are connected to insulated circuit substrates is reduced to four (the number of connection terminals is reduced by 50% compared to the case of FIG. 8). This configuration has more space for mounting semiconductor chips. However, this approach of simply reducing the number of connection terminals leads to an increase in parasitic inductance due to a change in the shapes of the connection terminals.

In addition, the PN main terminal 230 in the third reference example illustrated in FIG. 10 is configured so that the number of connection terminals that are connected to insulated circuit substrates is reduced to four, as in the case of FIG. 9.

Moreover, the PN main terminal 230 is configured so that the laminated portion between the horizontal portion 231c of the P main terminal 231 and the horizontal portion 232c of the N main terminal 232 is larger in area than the laminated portion between the horizontal portion 221c of the P main terminal 221 and the horizontal portion 222c of the N main terminal 222 in the PN main terminal 220 illustrated in FIG. 9. By expanding the laminated portion in this manner, the PN main terminal 230 reduces the increase in parasitic inductance caused by a change in the shapes of the connection terminals resulting from the reduction in the number of connection terminals.

However, the approach of simply expanding the laminated portion results in an insufficient inter-electrode insulation distance between the different potentials of the P main terminal 231 and the N main terminal 232. Moreover, the approach of simply expanding the laminated portion may make it difficult to perform bonding using an assembly tool. For example, during ultrasonic bonding of the PN main terminal 230 to insulated circuit substrates, an ultrasonic bonding tool may collide with parts existing around the laminated portion, making it difficult to ultrasonically bond the connection terminals at the predetermined locations on the insulated circuit substrates. This results in poor assembly workability during device assembly.

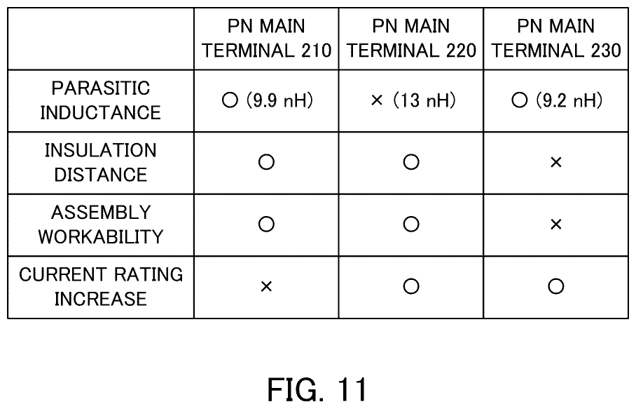

FIG. 11 illustrates the evaluation of the PN main terminals in the first, second, and third reference examples. FIG. 11 illustrates the evaluation of the PN main terminal 210 in the first reference example, the PN main terminal 220 in the second reference example, and the PN main terminal 230 in the third reference example, in terms of the following items: parasitic inductance, insulation distance, assembly workability, and current rating increase. In FIG. 11, a circle mark indicates that the requirement of an evaluation item is satisfied, whereas a cross mark indicates that the requirement is not satisfied. The parasitic inductance requirement is determined to be satisfied if parasitic inductance is 10 nH or less.

In the configuration of the PN main terminal 210 in the first reference example, the parasitic inductance is 9.9 nH, which satisfies the parasitic inductance requirement. The insulation distance between the P main terminal 211 and the N main terminal 213 and the insulation distance between the P main terminal 212 and the N main terminal 214 are secured, which satisfies the insulation distance requirement. There is no difficulty in assembly, which satisfies the assembly workability requirement. However, it is difficult to increase the current rating, which does not satisfy the current rating increase requirement.

In the configuration of the PN main terminal 220 in the second reference example, the parasitic inductance is 13 nH, which does not satisfy the parasitic inductance requirement. The insulation distance between the P main terminal 221 and the N main terminal 222 is secured, which satisfies the insulation distance requirement. There is no difficulty in assembly, which satisfies the assembly workability requirement. It is possible to increase the current rating, which satisfies the current rating increase requirement.

In the configuration of the PN main terminal 230 in the third reference example, the parasitic inductance is 9.2 nH, which satisfies the parasitic inductance requirement. It is difficult to secure the insulation distance between the P main terminal 231 and the N main terminal 232, which does not satisfy the insulation distance requirement. There is difficulty in assembly, which does not satisfy the assembly workability requirement. It is possible to increase the current rating, which satisfies the current rating increase requirement.

As described above, none of the PN main terminals 210 in the first reference example, the PN main terminals 220 in the second reference example, and the PN main terminals 230 in the third reference example satisfies the requirements of all items. Therefore, they are difficult to satisfy product specifications.

The following describes the main terminals 42 and 43 that form the external connection main terminal 40 in the present embodiment. In the following description, the main terminal 42 (first main terminal) may be referred to as the P main terminal 42, and the main terminal 43 (second main terminal) may be referred to as the N main terminal 43. In addition, the P main terminal 42 and the N main terminal 43 may collectively be referred to as the PN main terminal 40.

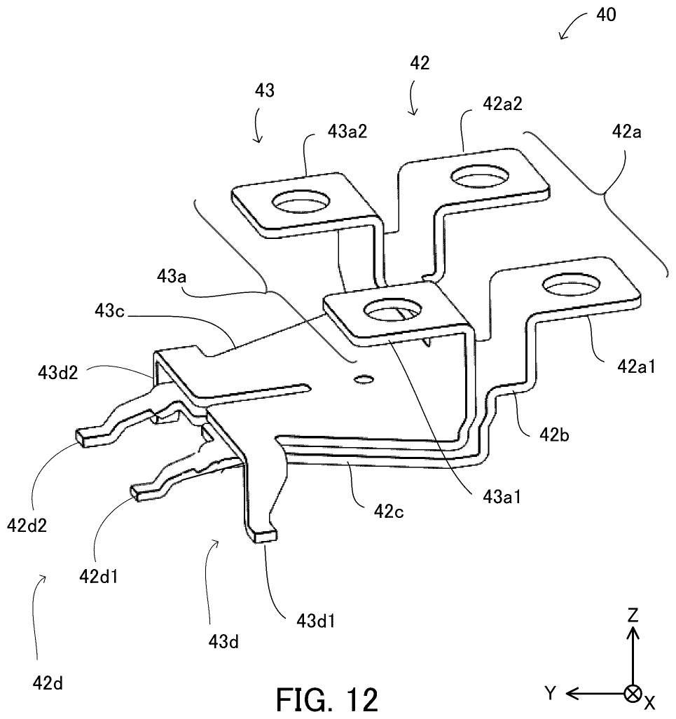

FIG. 12 illustrates an example of the configuration of a PN main terminal according to the present embodiment. The PN main terminal 40 includes the P main terminal 42 and the N main terminal 43. In this connection, the illustration of a terminal holding portion and insulator, which maintain the insulation between the P main terminal 42 and the N main terminal 43, is omitted.

One end of the P main terminal 42 is exposed on the upper surface of a case and serves as the external terminal 42a (positive external terminal) that connects to an external device (external power supply). The external terminal 42a is divided into the external terminals 42a1 and 42a2 in the horizontal direction (X direction). In addition, the P main terminal 42 includes the external terminal 42a, horizontal portion 42b, and horizontal portion 42c (first lead frame portion), arranged in this order from the one end toward the other. The horizontal portions 42b and 42c, which form a bus bar, are horizontal to the bottom surface of the device housing space. The height of the horizontal portion 42b is lower than that of the external terminal 42a, and the height of the horizontal portion 42c is lower than that of horizontal portion 42b.

The external terminal 42a and horizontal portions 42b and 42c are formed by bending the flat plate-shaped P main terminal 42 such that the external terminal 42a and the horizontal portion 42b are connected by a vertically extending connecting portion and the horizontal portions 42b and 42c are likewise connected by a vertically extending connecting portion. In addition, a first substrate connection portion 42d is formed at an edge of the horizontal portion 42c to extend obliquely therefrom toward insulated circuit substrates. The first substrate connection portion 42d includes the connection terminal 42d1 (first connection terminal) and the connection terminal 42d2 (second connection terminal).

The N main terminal 43 is placed over the P main terminal 42, and one end of the N main terminal 43 is exposed above the upper surface of the case and serves as an external terminal 43a (negative external terminal) that connects to the external device. The external terminal 43a is divided into the external terminals 43a1 and 43a2 in the horizontal direction (X direction). The N main terminal 43 includes the external terminal 43a and horizontal portion 43c (second lead frame portion), arranged in this order from the one end toward the other. The horizontal portion 43c, which is a bus bar, is horizontal to the bottom surface of the device housing space. The height of the horizontal portion 43c is lower than that of the external terminal 43a but higher than that of the horizontal portion 42c of the P main terminal 42. Moreover, the horizontal portion 43c is placed to form a laminated portion where the horizontal portion 43c is superimposed on the horizontal portion 42c of the P main terminal 42 with a predetermined distance therebetween.

The external terminal 43a and horizontal portion 43c are formed by bending the flat plate-shaped N main terminal 43 such that the external terminal 43a and the horizontal portion 43c are connected by a vertically extending connecting portion. In addition, a second substrate connection portion 43d is formed at an edge of the horizontal portion 43c to vertically extend therefrom toward insulated circuit substrates across the horizontal portion 42c. The second substrate connection portion 43d includes the connection terminal 43d1 (third connection terminal) and the connection terminal 43d2 (fourth connection terminal). Each of the connection terminals 42d1 and 42d2 of the P main terminal 42 and the connection terminals 43d1 and 43d2 of the N main terminal 43 is electrically and mechanically connected to a circuit pattern via solder. Alternatively, they are directly connected by laser welding or ultrasonic welding, for example.

The connection terminals 42d1 and 42d2 of the P main terminal 42 extend obliquely or vertically toward the corresponding insulated circuit substrates, and the connection terminals 43d1 and 43d2 of the N main terminal 43 extend obliquely or vertically from the horizontal portion 43c toward the corresponding insulated circuit substrates across the horizontal portion 42c.

FIG. 12 illustrates, as an example, a configuration in which the connection terminals 42d1 and 42d2 extend obliquely and the connection terminals 43d1 and 43d2 extend vertically. However, at least either the connection terminals 42d1 and 42d2 or the connection terminals 43d1 and 43d2 may extend obliquely toward the corresponding insulated circuit substrates.

That is, the connection terminals 43d1 and 43d2 may extend obliquely and the connection terminals 42d1 and 42d2 may extend vertically. Alternatively, the connection terminals 42d1 and 42d2 and the connection terminals 43d1 and 43d2 may all extend obliquely.

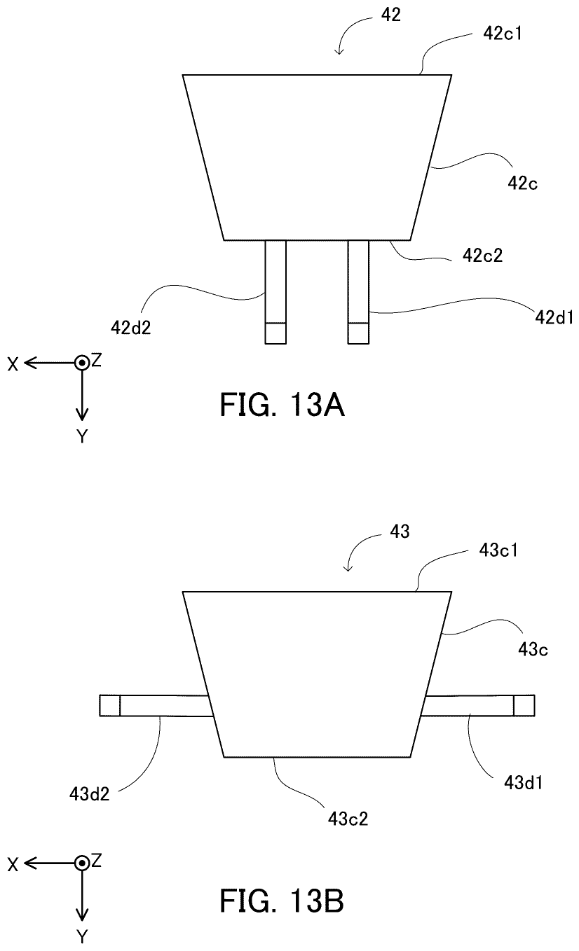

FIGS. 13A and 13B illustrate a first example of the extending directions of the connection terminals of the PN main terminal. FIG. 13A illustrates the extending directions of the connection terminals of the P main terminal, and FIG. 13B illustrates the extending directions of the connection terminals of the N main terminal. The horizontal portion 42c of the P main terminal 42 has a first trapezoidal shape that has a first long base 42c1 connected to the external terminal 42a and a first short base 42c2 and that narrows in width in the direction from the first long base 42c1 toward the connection terminals 42d1 and 42d2.

Likewise, the horizontal portion 43c of the N main terminal 43 has a second trapezoidal shape that has a second long base 43c1 connected to the external terminal 43a and a second short base 43c2 and that narrows in width in the direction from the second long base 43c1 toward the connection terminals 43d1 and 43d2.

Here, the connection terminal 42d1 of the P main terminal 42 extends from the horizontal portion 42c in the +Y direction and is connected to a predetermined insulated circuit substrate. The connection terminal 42d2 of the P main terminal 42 extends from the horizontal portion 42c in the +Y direction and is connected to a predetermined insulated circuit substrate. The connection terminal 43d1 of the N main terminal 43 extends from the horizontal portion 43c in the −X direction and is connected to a predetermined insulated circuit substrate. The connection terminal 43d2 of the N main terminal 43 extends from the horizontal portion 43c in the +X direction and is connected to a predetermined insulated circuit substrate.

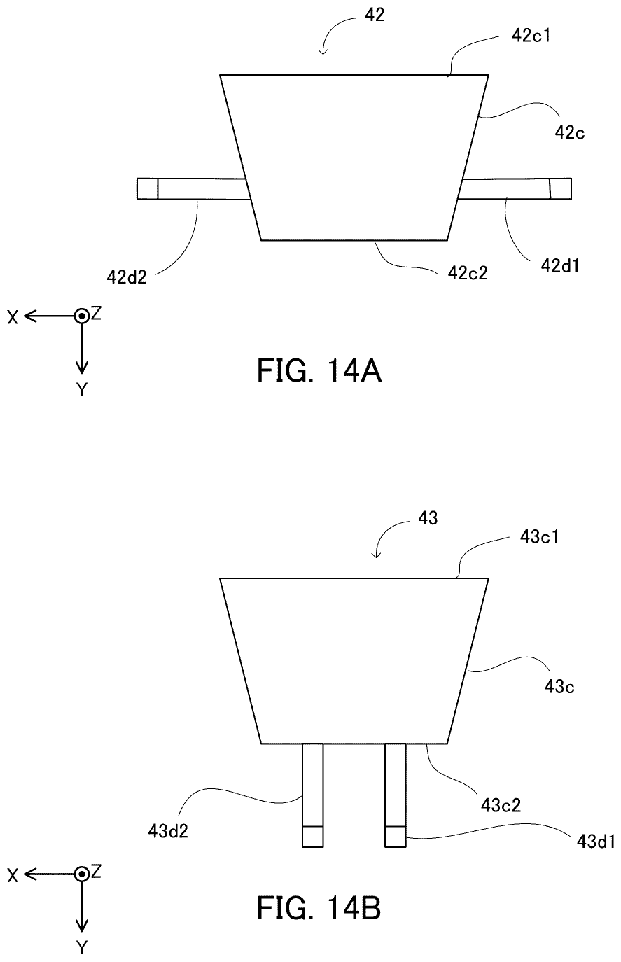

FIGS. 14A and 14B illustrate a second example of the extending directions of the connection terminals of the PN main terminal. FIG. 14A illustrates the extending directions of the connection terminals of the P main terminal, and FIG. 14B illustrates the extending directions of the connection terminals of the N main terminal. The connection terminal 42d1 of the P main terminal 42 extends from the horizontal portion 42c in the −X direction and is connected to a predetermined insulated circuit substrate. The connection terminal 42d2 of the P main terminal 42 extends from the horizontal portion 42c in the +X direction and is connected to a predetermined insulated circuit substrate. The connection terminal 43d1 of the N main terminal 43 extends from the horizontal portion 43c in the +Y direction and is connected to a predetermined insulated circuit substrate. The connection terminal 43d2 of the N main terminal 43 extends from the horizontal portion 43c in the +Y direction and is connected to a predetermined insulated circuit substrate. As described above, the extending directions of the connection terminals may have a pattern opposite to the extending directions of the connection terminals illustrated in FIGS. 13A and 13B.

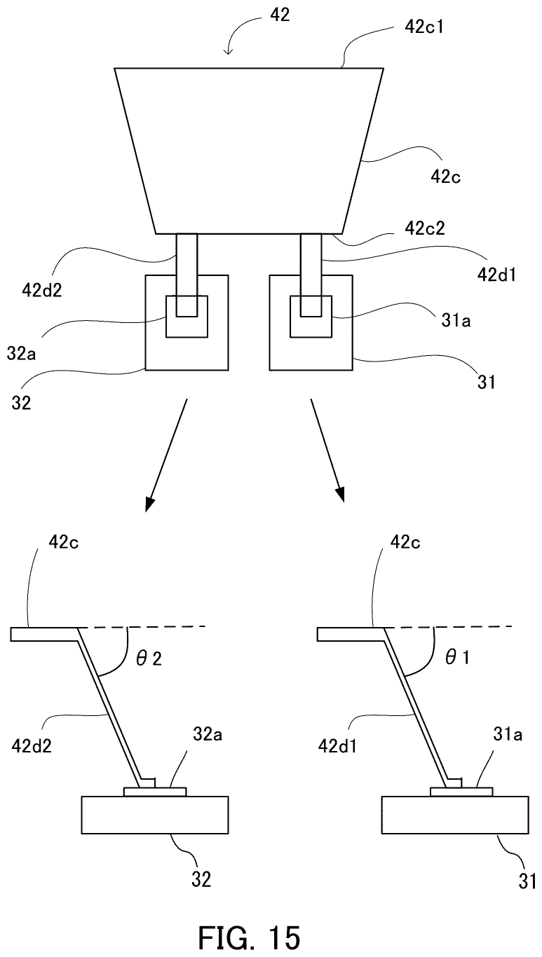

FIG. 15 is a view for describing the inclination angles and connection positions of the connection terminals provided in the P main terminal. In the case where the connection terminal 42d1 of the P main terminal 42 extends obliquely toward the insulated circuit substrate 31 (first insulated circuit substrate), the angle θ1 of the connection terminal 42d1 with respect to the horizontal plane of the horizontal portion 42c ranges from 30° to 80°, inclusive. Therefore, the connection terminal 42d1 is bonded at the angle θ1 to the circuit pattern 31a (first circuit pattern) on the insulated circuit substrate 31.

In addition, in the case where the connection terminal 42d2 of the P main terminal 42 extends obliquely toward the insulated circuit substrate 32 (second insulated circuit substrate), the angle θ2 of the connection terminal 42d2 with respect to the horizontal plane of the horizontal portion 42c ranges from 30° to 80°, inclusive. Therefore, the connection terminal 42d2 is bonded at the angle θ2 to the circuit pattern 32a (second circuit pattern) on the insulated circuit substrate 32.

The angles θ1 and θ2 are each preferably between 45° to 60°. The angles θ1 and θ2 may be set to be equal to each other or different from each other as long as they are within the above angular range.

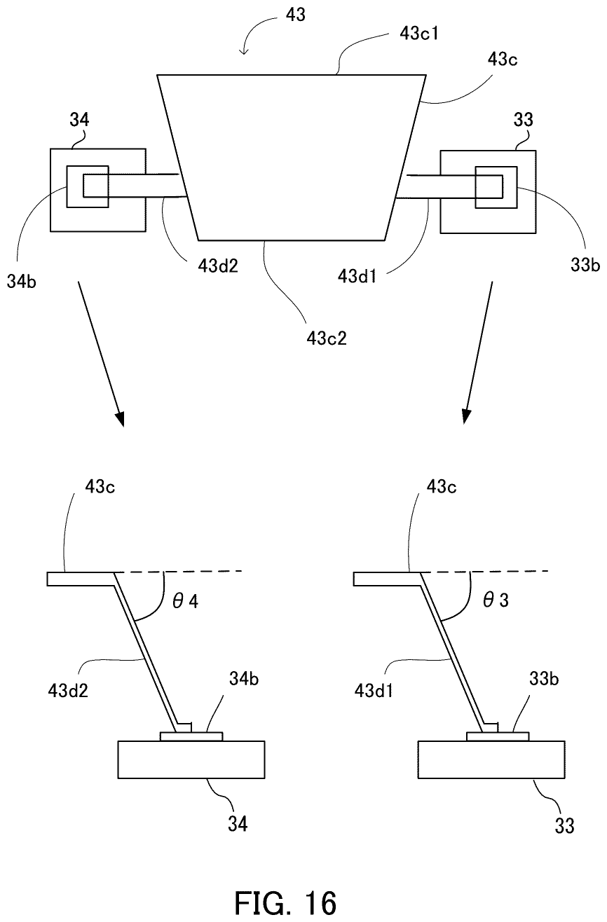

FIG. 16 is a view for describing the inclination angles and connection positions of the connection terminals provided in the N main terminal. In the case where the connection terminal 43d1 of the N main terminal 43 extends obliquely toward the insulated circuit substrate 33 (third insulated circuit substrate), the angle θ3 of the connection terminal 43d1 with respect to the horizontal plane of the horizontal portion 43c ranges from 30° to 80°, inclusive. Therefore, the connection terminal 43d1 is bonded at the angle θ3 to the circuit pattern 33b (third circuit pattern) on the insulated circuit substrate 33.

In the case where the connection terminal 43d2 of the N main terminal 43 extends obliquely toward the insulated circuit substrate 34 (fourth insulated circuit substrate), the angle θ4 of the connection terminal 43d2 with respect to the horizontal plane of the horizontal portion 43c ranges from 30° to 80°, inclusive. Therefore, the connection terminal 43d2 is bonded at the angle θ4 to the circuit pattern 34b (fourth circuit pattern) on the insulated circuit substrate 34.

In this connection, the angles θ3 and θ4 are each preferably between 45° to 60°. The angles θ3 and θ4 may be set to be equal to each other or different from each other as long as they are within the above angular range.

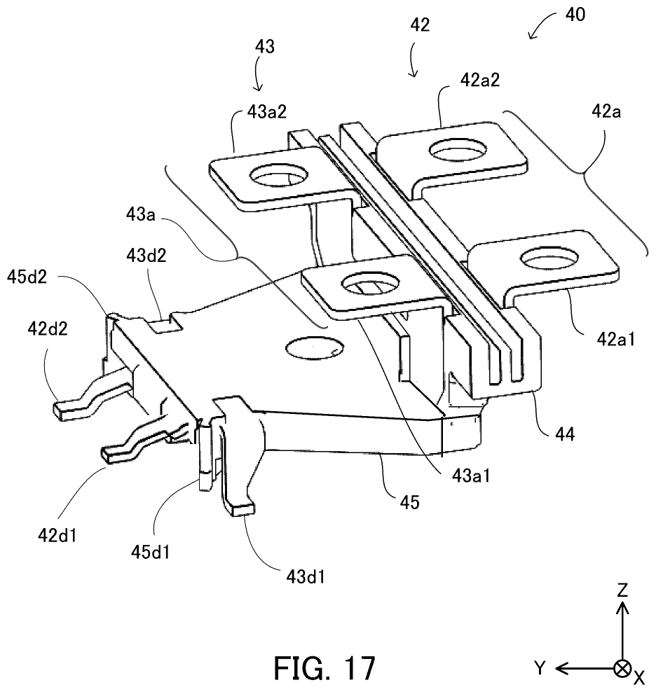

FIG. 17 illustrates an example of the configuration of the PN main terminal according to the present embodiment. FIG. 17 illustrates the PN main terminal 40 illustrated in FIG. 12, together with the terminal holding portion 44 and an insulator 45 that maintain the insulation between the P main terminal 42 and the N main terminal 43. Since the terminal holding portion 44 has already been described with reference to FIG. 3, its description is omitted.

The insulator 45 is molded to surround the horizontal portion 42c of the P main terminal 42 and the horizontal portion 43c of the N main terminal 43 and to fill the space in the laminated portion that is the overlapping area where the second trapezoidal shape of the horizontal portion 43c is superimposed on the first trapezoidal shape of the horizontal portion 42c. The molded insulator 45 maintains the insulation in the laminated portion between the horizontal portion 42c of the P main terminal 42 and the horizontal portion 43c of the N main terminal 43.

Moreover, the insulator 45 has a projection 45d1 that is positioned between the connection terminal 42d1 of the P main terminal 42 and the connection terminal 43d1 of the N main terminal 43, and a projection 45d2 that is positioned between the connection terminal 42d2 of the P main terminal 42 and the connection terminal 43d2 of the N main terminal 43.

The insulator 45 may be made of the same material as the terminal holding portion 44 and the case 22. That is, the insulator 45 is made of a thermoplastic resin. Examples of the resin here include a polyphenylene sulfide resin, a polybutylene terephthalate resin, a polybutylene succinate resin, a polyamide resin, and an acrylonitrile butadiene styrene resin.

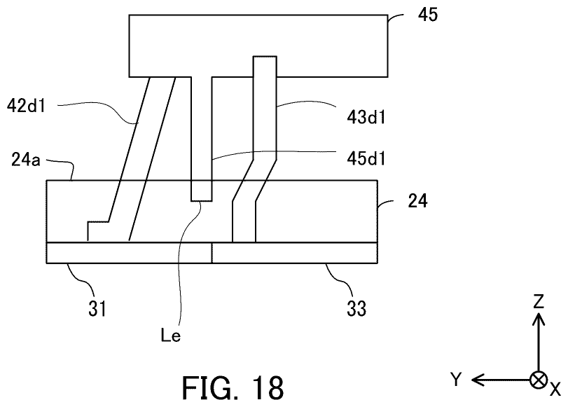

FIG. 18 is a view for describing a projection of an insulator. The projection 45d1 is formed to project from the insulator 45 and to be positioned between the connection terminal 42d1 of the P main terminal 42 connected to the insulated circuit substrate 31 and the connection terminal 43d1 of the N main terminal 43 connected to the insulated circuit substrate 33. The sealing material 24 is applied up to a point above the lower end Le of the projection 45d1 That is, the lower end Le of the projection 45d1 is placed lower than the upper surface 24a of the sealing material 24.

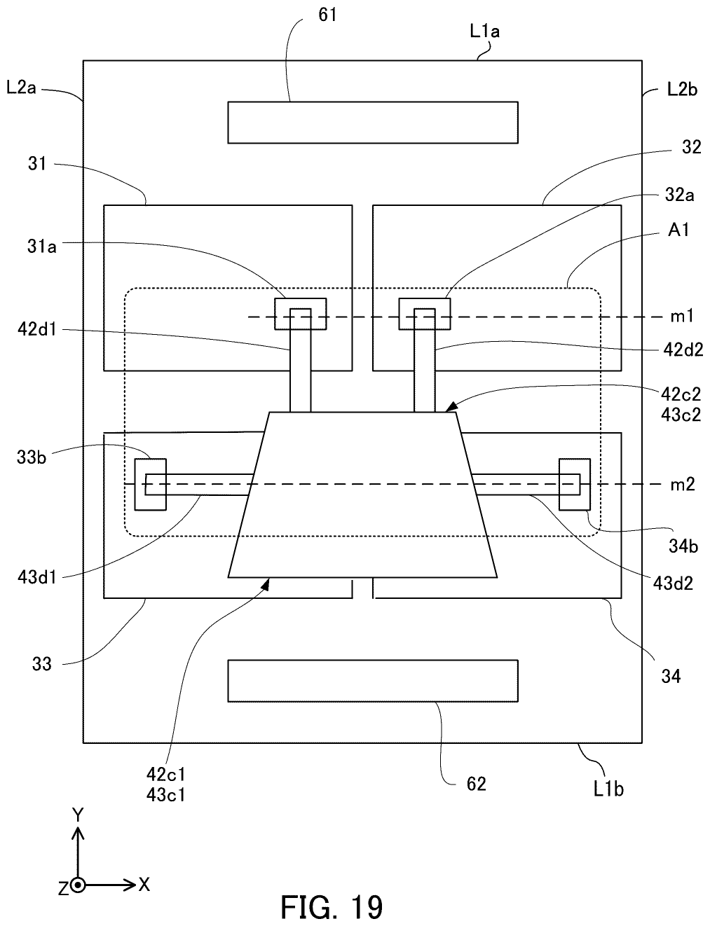

FIG. 19 illustrates an example of a connection area of the PN main terminal. The semiconductor device 10 has a rectangular device shape and has a short side L1a (first short side) and a short side L1b (second short side) that are the short sides thereof, and a long side L2a (first long side) and a long side L2b (second long side) that are the long sides thereof.

Here, a first direction is defined as a −Y direction from the short side L1a toward the short side L1b, and a second direction is defined as a +X direction from the long side L2a toward the long side L2b. The insulated circuit substrate 33 is disposed in the first direction with respect to the insulated circuit substrate 31, and the insulated circuit substrate 32 is disposed in the second direction with respect to the insulated circuit substrate 31. In addition, the insulated circuit substrate 34 is disposed in the first direction with respect to the insulated circuit substrate 32 and in the second direction with respect to the insulated circuit substrate 33.

In addition, a connection area A1 is defined as an area that corresponds to a central part located between the middle points of the long sides of the device shape in the semiconductor device 10 and that includes the area where the insulated circuit substrates 31 and 33 face each other and the area where the insulated circuit substrates 32 and 34 face each other. The first short base 42c2 of the horizontal portion 42c and the second short base 43c2 of the horizontal portion 43c are located in this connection area A1. In addition, the first long base 42c1 of the horizontal portion 42c and the second long base 43c1 of the horizontal portion 43c are located in the vicinity of the short side L1b. In addition, a line segment m1 (first line segment) connecting the connection terminals 42d1 and 42d2 and a line segment m2 (second line segment) connecting the connection terminals 43d1 and 43d2 are parallel to each other.

Here, in the configuration of the PN main terminal 40 described above in the present embodiment, the PN main terminal 40 is configured so that both the horizontal portion 42c of the P main terminal 42 and the horizontal portion 43c of the N main terminal 43 are trapezoidal-shaped. Therefore, the laminated portion between the horizontal portion 42c and the horizontal portion 43c that are arranged in proximity has a trapezoidal shape with an increased area, which reduces parasitic inductance and thus enables a reduction in the switching loss of the switching elements included in semiconductor chips.

Furthermore, at least either the connection terminals 42d1 and 42d2 provided in the horizontal portion 42c or the connection terminals 43d1 and 43d2 provided in the horizontal portion 43c are designed to be connected at an inclined angle to insulated circuit substrates. This configuration shortens the length of the P main terminal 42 in the non-laminated portion and the length of the N main terminal 43 in the non-laminated portion, which further reduces the parasitic inductance.

In addition, the insulator 45 is molded to surround the horizontal portion 42c and the horizontal portion 43c and to have the projection 45d1, which is positioned between the connection terminal 42d1 of the P main terminal 42 and the connection terminal 43d1 of the N main terminal 43, and the projection 45d2, which is positioned between the connection terminal 42d2 of the P main terminal 42 and the connection terminal 43d2 of the N main terminal 43. This ensures the insulation between the opposing electrodes of the P main terminal 42 and N main terminal 43. Furthermore, since the sealing material 24 is applied to a point above the lower ends Le of the projections of the insulator 45, the insulation between the opposing electrodes of the P main terminal 42 and N main terminal 43 is further enhanced.

Still further, the trapezoidal horizontal portion 42c narrows in width toward the connection terminals 42d1 and 42d2, which are connected to insulated circuit substrates, and the trapezoidal horizontal portion 43c narrows in width toward the connection terminals 43d1 and 43d2, which are connected to insulated circuit substrates. This expands the laminated portion, as well as reducing the parasitic inductance and improving the assembly workability (clearance) during device assembly.

As to the assembly workability, for example, an ultrasonic bonding tool does not collide with any part existing around the laminated portion during the ultrasonic bonding of the PN main terminal 40 to the insulated circuit substrates, which makes it possible to ultrasonically bond the connection terminals at the predetermined locations on the insulated circuit substrates. This enables easy bonding using the assembly tool.

Furthermore, the PN main terminal 40 is connected to the insulated circuit substrates via the connection terminals 42d1, 42d2, 43d1, and 43d2, without increasing the number of connections to the insulated circuit substrates. This reduces the terminal connection areas and enhances the internal layout efficiency, which makes it possible to increase the current rating.

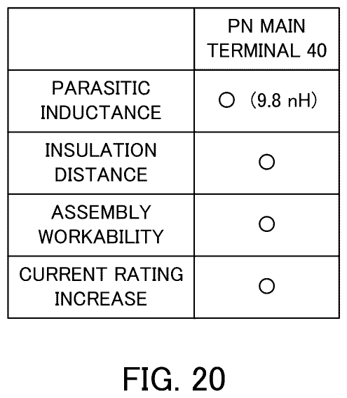

FIG. 20 illustrates the evaluation of the PN main terminal according to the present embodiment. FIG. 20 illustrates the evaluation of the PN main terminal 40 in terms of the following items: parasitic inductance, insulation distance, assembly workability, and current rating increase.

The parasitic inductance is 9.8 nH that is below 10 nH, which satisfies the parasitic inductance requirement. The insulation distance between the P main terminal 42 and the N main terminal 43 is secured, which satisfies the insulation distance requirement (the insulation distance between the different potentials in the PN main terminal is able to handle a voltage up to 3.3 kV). There is no difficulty in assembly workability, which satisfies the assembly workability requirement. Furthermore, it is possible to increase the current rating, which satisfies the current rating increase requirement. As the PN main terminal 40 satisfies the requirements of all the items as described above, it is possible to satisfy product specifications.

According to one aspect, it is achieved to reduce parasitic inductance and accordingly reduce switching loss.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
an insulated circuit substrate group including a plurality of insulated circuit substrates that are arranged on one plane; and
an external connection main terminal formed of a first main terminal and a second main terminal in an integral manner,
the first main terminal including
a positive external terminal connected to a positive electrode of an external power supply,
a first lead frame portion having a first planar trapezoidal shape parallel to the one plane, and being connected to the positive external terminal, and
a first substrate connection portion extending obliquely or vertically from an edge of the first lead frame portion toward the insulated circuit substrate group,
the second main terminal placed over the first main terminal and including
a negative external terminal connected to a negative electrode of the external power supply,
a second lead frame portion having a second planar trapezoidal shape parallel to the one plane, and being connected to the negative external terminal, the second lead frame portion located over the first lead frame portion having a predetermined gap therebetween in a direction orthogonal to the one plane, and
a second substrate connection portion extending obliquely or vertically from an edge of the second lead frame portion toward the insulated circuit substrate group.

2. The semiconductor device according to claim 1, wherein at least one of the first substrate connection portion or the second substrate connection portion extends obliquely toward the insulated circuit substrate group.

3. The semiconductor device according to claim 2, wherein
the first substrate connection portion extends obliquely at an angle in a range of 30° to 80° with respect to the first lead frame portion, and
the second substrate connection portion extends obliquely at an angle in a range of 30° to 80° with respect to the second lead frame portion.

4. The semiconductor device according to claim 1, further comprising a molded insulator surrounding the first lead frame portion and the second lead frame portion to fill the gap between the first lead frame portion and the second lead frame portion.

5. The semiconductor device according to claim 4, wherein the molded insulator includes a projection located between the first substrate connection portion and the second substrate connection portion.

6. The semiconductor device according to claim 5, further comprising a sealing material, an upper surface of the sealing material being located at a position above a lower end of the projection so that the insulated circuit substrate group is covered by the sealing material.

7. The semiconductor device according to claim 1, wherein
the first trapezoidal shape of the first lead frame portion has a first long base connected to the positive external terminal and a first short base, and narrows in width in a direction from the first long base thereof toward the first short base thereof, and
the second trapezoidal shape of the second lead frame portion has a second long base connected to the negative external terminal and a second short base, and narrows in width in a direction from the second long base thereof toward the second short base thereof.

8. The semiconductor device according to claim 7, wherein
the semiconductor device has a rectangular substrate placement area with a first short side and a second short side that are parallel to each other and extend in a short side direction, and a first long side and a second long side that are parallel to each other and extend in a long side direction,
the insulated circuit substrate group includes a first insulated circuit substrate, a second insulated circuit substrate, a third insulated circuit substrate, and a fourth insulated circuit substrate, and
the first insulated circuit substrate and the second insulated circuit substrate are aligned in the short side direction and face the first short side, the third insulated circuit substrate and the fourth insulated circuit substrate are aligned in the short side direction and face the second short side,
the first short base of the first lead frame portion and the second short base of the second lead frame portion are located in a connection area that is a central part of the substrate placement area located in a middle of the first and second long sides and that includes an area where the first and third insulated circuit substrates face each other and an area where the second and fourth insulated circuit substrates face each other, and
the first and second long bases of the first and second lead frame portions are located in a vicinity of the second short side.

9. The semiconductor device according to claim 8, wherein
the first to fourth insulated circuit substrates include first to fourth circuit patterns in the connection area, respectively,
the first substrate connection portion includes a first connection terminal connected to the first circuit pattern and a second connection terminal connected to the second circuit pattern, and
the second substrate connection portion includes a third connection terminal connected to the third circuit pattern and a fourth connection terminal connected to the fourth circuit pattern.

10. The semiconductor device according to claim 9, wherein a first line segment connecting a connection point of the first connection terminal and the first circuit pattern to a connection point of the second connection terminal and the second circuit pattern is parallel to a second line segment connecting a connection point of the third connection terminal and the third circuit pattern to a connection point of the fourth connection terminal and the fourth circuit pattern.

11. An external connection main terminal, comprising:
a first main terminal including
a positive external terminal connectable to a positive electrode of an external power supply,
a first lead frame portion of a first planar trapezoidal shape parallel to one plane, and being connected to the positive external terminal, and
a first substrate connection portion extending obliquely or vertically with respect to the one plane from an edge of the first lead frame portion; and
a second main terminal placed over the first main terminal, the second main terminal including
a negative external terminal connectable to a negative electrode of the external power supply,
a second lead frame portion of a second planar trapezoidal shape parallel to the one plane, and being connected to the negative external terminal, the second lead frame portion being located over the first lead frame portion and having a predetermined gap therebetween in a direction orthogonal to the one plane, and
a second substrate connection portion extending obliquely or vertically with respect to the one plane from an edge of the second lead frame portion.

12. The external connection main terminal according to claim 11, wherein at least one of the first substrate connection portion or the second substrate connection portion extends obliquely with respect to the one plane.

13. The external connection main terminal according to claim 12, wherein
the first substrate connection portion extends obliquely at an angle in a range of 30° to 80° with respect to the first lead frame portion, and
the second substrate connection portion extends obliquely at an angle in a range of 30° to 80° with respect to the second lead frame portion.

14. The external connection main terminal according to claim 11, further comprising a molded insulator surrounding the first lead frame portion and the second lead frame portion to fill the gap between the first lead frame portion and the second lead frame portion.

15. The external connection main terminal according to claim 14, wherein the molded insulator includes a projection located between the first substrate connection portion and the second substrate connection portion.

16. The external connection main terminal according to claim 15, further comprising a sealing material applied to a point above a lower end of the projection.

17. The external connection main terminal according to claim 11, wherein
the first trapezoidal shape of the first lead frame portion has a first long base connected to the positive external terminal and a first short base, and narrows in width in a direction from the first long base toward the first short base thereof, and
the second trapezoidal shape of the second lead frame portion has a second long base connected to the negative external terminal and a second short base, and narrows in width in a direction from the second long base toward the second short base thereof.

18. The external connection main terminal according to claim 17, wherein
a device including an insulated circuit substrate group in the one plane has a rectangular substrate placement area with a first short side and a second short side that are parallel to each other and extend in a short side direction, and a first long side and a second long side that are parallel to each other and extend in a long side direction,
the insulated circuit substrate group includes a first insulated circuit substrate, a second insulated circuit substrate, a third insulated circuit substrate, and a fourth insulated circuit substrate, and
the first insulated circuit substrate and the second insulated circuit substrate are aligned in the short side direction and face the first short side, the third insulated circuit substrate and the fourth insulated circuit substrate are aligned in the short side direction and face the second short side,
the first short base of the first lead frame portion and the second short base of the second lead frame portion are located in a connection area that is a central part of the substrate placement area located in a middle of the first and second long sides and that includes an area where the first and third insulated circuit substrates face each other and an area where the second and fourth insulated circuit substrates face each other, and
the first and second long bases of the first and second lead frame portions are located in a vicinity of the second short side.

19. The external connection main terminal according to claim 18, wherein
the first to fourth insulated circuit substrates include first to fourth circuit patterns in the connection area, respectively,
the first substrate connection portion includes a first connection terminal connected to the first circuit pattern and a second connection terminal connected to the second circuit pattern, and
the second substrate connection portion includes a third connection terminal connected to the third circuit pattern and a fourth connection terminal connected to the fourth circuit pattern.

20. The external connection main terminal according to claim 19, wherein a first line segment connecting a connection point of the first connection terminal and the first circuit pattern to a connection point of the second connection terminal and the second circuit pattern is parallel to a second line segment connecting a connection point of the third connection terminal and the third circuit pattern to a connection point of the fourth connection terminal and the fourth circuit pattern.
